(19) United States
(12) Patent Application Publication
(10) Pub. No.: US 2012/0217519 A1
(43) Pub. Date: Aug. 30, 2012

(54) METHOD AND STRUCTURE FOR ENCAPSULATING SOLID-STATE LIGHT EMITTING CHIP AND LIGHT SOURCES USING THE ENCAPSULATION STRUCTURE

(75) Inventors: Yanzheng Xu, Shenzhen (CN); Quan Zhang, Wuhan, CA (US)

(73) Assignee: APPOTRONICS CORPORATION LIMITED, Guangdong (CN)

(21) Appl. No.: 13/502,671

(22) PCT Filed: Nov. 19, 2010
(86) PCT No.: PCT/CN10/01855

§ 371 Date: Apr. 18, 2012

(30) Foreign Application Priority Data
Nov. 19, 2009 (CN) 200910189520.0

(51) Int. Cl. H01L 27/15; H01L 33/58; H01L 33/52

(52) U.S. Cl. 257/88; 438/27; 257/98; 257/E33.073; 257/E27.121; 257/E33.059

(57) ABSTRACT

A structure and a method for encapsulating a solid-state lighting chip (1) are provided. The structure includes the following parts: a heat sink base (2) is provided; a single solid-state lighting chip (1) or multiple solid-state lighting chips distributed as an array are positioned or packaged on the heat sink base (2); the lighting surface of the solid-state lighting chip (1) is set as a bare surface; a single alignment unit (5) or multiple alignment units distributed as an array are positioned above the solid-state lighting chip (1) and aligned with the solid-state lighting chip (1), in order to output a nearly parallel light which is aligned from the light of the solid-state lighting chip (1). A light source device or a lamp device with the light source device using the encapsulating structure or the method, has the advantages of low levels of light expansion, and high brightness, high power light output with low cost.

### BACKGROUND OF THE INVENTION

### Field of the Invention

This invention relates to solid-state light emitting devices, such as semiconductor light emitting device, and in particular, it relates to an encapsulating method and structure for solid-state light emitting devices.

### Description of the Related Art

Conventional high power stage lighting sources primarily use metal halide discharge lamps. Metal halide discharge lamps are white light sources, and their life is relatively short, from a few hundred to a few thousand hours. Because the emitting spectrum of metal halide discharge lamps is a continuous white spectrum, different monochromatic lights required by stage lighting are achieved using color filters. Patterns projected by such color lights have relatively low color saturation; their colors are not very vivid or very rich.

Solid-state light sources, including semiconductor light emitting devices (such as but not limited to light emitting diodes), which can emit light (such as but not limited to visible light) under a drive electrical current, are clean and energy-efficient light sources. Compared to conventional light sources, solid-state light sources have the advantages of relatively long life, low energy consumption, adjustable wavelength, etc. Due to limitations in heat dissipation and low light flux of current LED (light emitting diodes), LED light sources are currently primarily used in low power, low end color-adjustable lighting products. If high power stage lights can employ LED light source, color filters can be omitted; moreover, changing the drive currents of different base color LEDs can achieve color adjustment of the light source. As a result, by using monochromatic LEDs with high color saturation, the color rendering properties of state lights can be significantly improved. However, currently used LEDs generate a significant amount of heat and have relatively low light emitting efficiency, so single LED chips cannot withstand high power. For this reason, the high flux required by high power stage lighting is typically achieved by LED arrays or LED chip arrays. For example, Chinese Patent Application No. 200720061982.0 discloses a light source assembly for stage lighting, which uses an LED array and a large heat dissipation structure to provide a 100 W light power.

Current high power LED chips are typically about 1×1 mm in size and about 100 μm in thickness. The GaN material used in blue LED chips has a refractive index of 2.5; the AlGaInP material used in green LED chips has a refractive index of 3.4; while the refractive index of air is 1. Due to the large difference between the refractive indices of the LED chips and air, the critical angles of the output light from the LED chips are relatively small. Light emitted by the

LED chip having an exit angle larger than the critical angle will be reflected back, resulting in large loss. In current light sources, to increase light emitting efficiency, the LED encapsulation structures often employ a hemispherical lens disposed directly above the LED chip, to reduce loss caused to light reflection due to critical angle. Or, a thin silicone layer is coated over the LED chip, to both increase the transmission efficiency of the generated light and protect the chip from mechanical damage.

The current technology described above have certain disadvantages. LED chips employing the above encapsulation structures can only be used in products that do not have an output angle requirement, such as color changing lights, wash lamp, etc., where the output light is directed onto walls directly, or is projected onto walls by secondary optics. Because such systems do not use projection lenses, the output angle of the LED light source is not a concern, and higher flux is desirable. However, for high power LED pattern projection lighting systems or similar systems, due to requirements imposed by the optical imaging system on the angles of the light, limitations imposed by the size of the imaging system, high image quality requirements, and high brightness requirement of the system, the LED light sources for such systems are required to have high output light flux as well as low etendue in order to increase the optical efficiency of the overall system.

### SUMMARY OF THE INVENTION

Accordingly, the present invention is directed to an encapsulation method and structure for solid-state light emitting chips that substantially obviates one or more of the problems due to limitations and disadvantages of the related art. The light sources using such encapsulation method and structure can achieve lower etendue which increases the optical efficiency of the overall system.

To solve problems of the current technology described above, embodiments of the present invention make the following improvements. Current light sources typically use an optical medium with certain refractive index to directly encapsulate the light emitting surface of the solid-state light emitting chips to increase light flux; however, due to requirements on light angles and high brightness imposed by the imaging system, it is desirable to reduce the etendue of the light source. To achieve this, embodiments of the present invention employs a structure that improves (decreases) etendue, even though the light flux is somewhat decreased. This structure is more suitable for light sources used in imaging systems. The encapsulation structure according to embodiments of the present invention eliminates the optical medium that is placed directly on the light emitting surface, so the light emitting surfaces of the solid-state light emitting chips are bare.

To achieve these and other advantages and in accordance with the purpose of the present invention, the present invention provides a method for encapsulating solid-stage light emitting chips, which includes: providing a solid-state light emitting chip, or multiple solid-state light emitting chip forming an array, directly on a heat dissipating base, a light emitting surface of each solid-state light emitting chip being bare; and providing a collimating device, or multiple collimating devices forming an array, each collimating device being aligned with a solid-state light emitting chip, to collimate lights emitted by the solid-state light emitting chips into near-parallel lights for output.

More specifically, in the above method, the collimating devices are focusing lens, and the multiple focusing lenses are joined to each other and formed integrally. A support frame placed on the heat dissipating base may be used to support the collimating devices, so that each collimating device is located directly above the corresponding solid-state light emitting chip. The solid-state light emitting chips may be semiconductor light emitting chips, and in particular, they may be light emitting diode chips.

In another aspect, the present invention provides an encapsulation structure for solid-stage light emitting chips, which includes: a heat dissipating base; a solid-state light emitting chip, or multiple solid-state light emitting chip forming an array, disposed on the heat dissipating base, a light emitting surface of each solid-state light emitting chip being bare and exposed to air; and a collimating device, or multiple collimating devices forming an array, each collimating device being disposed above and aligned with a solid-state light emitting chip, to collimate lights emitted by the solid-state light emitting chips into near-parallel lights for output.

The encapsulation structure further includes a support frame placed on the heat dissipating base for supporting the collimating devices. It further includes an encapsulating shell structure joining the heat dissipating base and the collimating devices, forming a space between the heat dissipating base and the collimating devices to accommodate the solid-state light emitting chips.

In the encapsulation structure, a distance between each collimating device and the light emitting surface of the corresponding solid-state light emitting chip is no larger than 50% of a diameter of a bounding circle of the solid-state light emitting chip.

In another aspect, the present invention provides a light source including the solid-state light emitting chips and the encapsulation structure described above.

In yet another aspect, the present invention provides a lighting device, which includes: a heat dissipating base; three solid-state light emitting chip arrays disposed on the heat dissipating base, each being formed by multiple solid-state light emitting chips emitting at common wavelengths, a light emitting surface of each solid-state light emitting chip being bare and exposed to air; a plurality of collimating device arrays, each being formed by multiple collimating devices, each collimating device being disposed above and aligned with a solid-state light emitting chip, to collimate lights emitted by the solid-state light emitting chips into near-parallel lights for output; a light combining device for combining light from the three solid state light emitting chip arrays via the collimating device arrays into one light beam; a pattern plate or a pattern carried on the pattern plate; and a focusing lens receiving the combined light beam and focusing it onto the pattern plate or the pattern.

Lighting devices according to embodiments of the present invention have simple structures, low cost, and are easy to manufacture.

### BRIEF DESCRIPTION OF THE DRAWINGS

FIG. 1 illustrates a first conventional LED encapsulation structure.

FIGS. 2a and 2b illustrate a second conventional LED encapsulation structure, where FIG. 2b is a partial detailed illustration of FIG. 2a.

FIG. 3 illustrates an encapsulation structure for a single LED chip according to an embodiment of the present invention.

FIG. 4 illustrates an encapsulation structure for multiple LED chips according to an embodiment of the present invention.

FIG. 5 illustrates a stage lighting system employing a light source according to an embodiment of the present invention. In the figures, the reference symbols are: 1—LED chip; 11—PN junction; 2—heat dissipating device or heat dissipating base; 3—lens; 4—silicone protective layer; 5—focusing lens; 6—support frame.

### DETAILED DESCRIPTION OF THE PREFERRED EMBODIMENTS

Embodiments of the present invention are described below with reference to the drawings.

FIG. 1 illustrates a current encapsulation structure for solid-state light emitting chips using LED as an example. A high power LED chip 1 is directly disposed on a heat dissipating base 2. The heat dissipating base 2 may be the substrate of the LED chip 1, where electrodes are formed outside of the light emitting area of the substrate. A hemispherical lens 3 made of silicone or plastic is disposed over the LED chip 1 to protect the LED chip surface and the electrical connections from mechanical damage, and at the same time increase the light flux of the light source, in order to maximize the flux. As an important parameter that measures the light throughput capacity of the light source, etendue is expressed as:

E=n².s. sin²(α)

where n is the refractive index of the lens 3, s is the light emitting area of the light source, and α is the half-angle of the light divergence of the light source. According to this formula, using a typical refractive index of n=1.46 for silicone, by employing the lens 3 in the encapsulation, the etendue E of the light source is increased by a factor of approximately two as compared to a bare LED chip. However, the light flux of the light source is not increased by a factor of two, so this system is not suitable for stage lighting or products that include a projection system such as a projector.

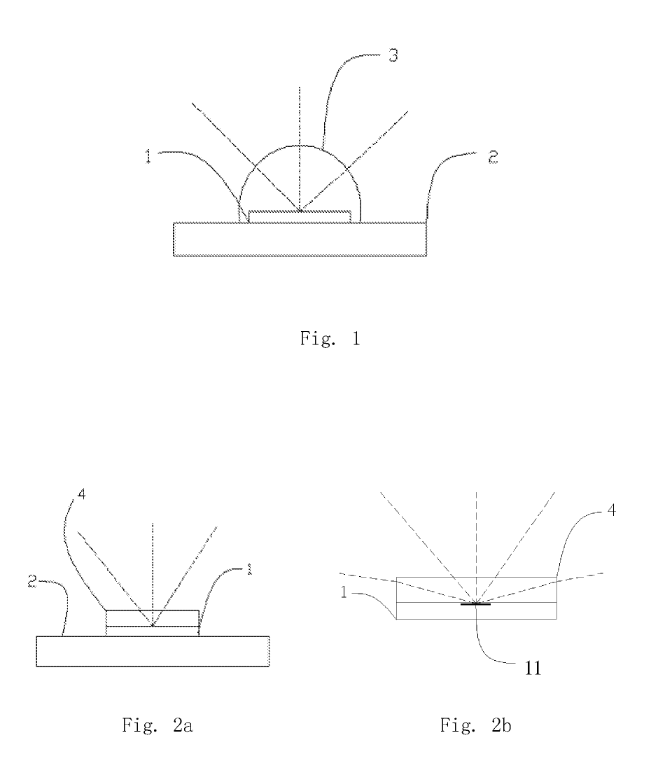

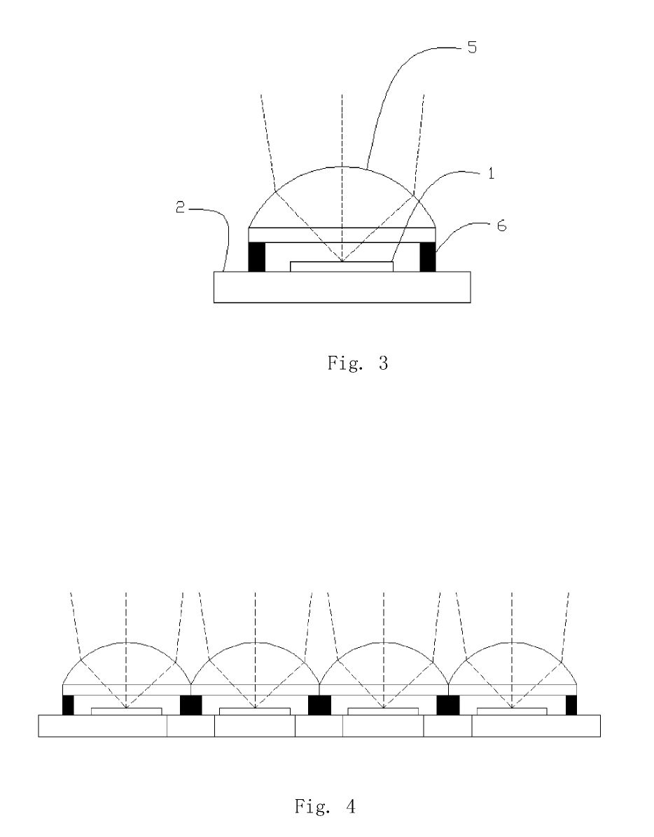

FIG. 2a illustrates another encapsulation structure. A high power LED chip 1 is directly disposed on a heat dissipating base 2, and a thin silicone protective layer 4 is coated over the LED chip 1. If the area of the silicone coating 4 is infinitely large, according to the above formula, the etendue E of the light source is increased by a factor of n² as compared to a bare LED chip. However, in practice, as shown in FIG. 2b, the area of the silicone coating 4 is often only slightly larger than the area of the LED chip. Assuming that the distance from the light-emitting PN junction 11 of the LED chip 1 to the top surface of the chip is 3-5 μm, the chip size is 1×1 mm, and the thickness of the silicone layer 4 is larger than 100 μm which is typically the case, then a part of the emitted light will escape from the side edge of the silicone layer 4. As a result, the light source now emits from both the top surface and the side surface of the silicone layer, as opposed to only emitting from the top surface as in a bare LED chip. Thus, the etendue should be E=(s+s1).sin²(α) where s1 is the area of the side surface of the silicone layer. It can be seen that the etendue of the light source using this encapsulation structure is larger than that of the structure shown in FIG. 1. Because the light flux is not increased proportionally, such a system is likewise not suitable for stage lighting or products that include a projection system.

Based on the above considerations, encapsulation structures according to embodiments of the present invention eliminate the use of lens 3 or silicone layer 4. Instead, a solid-state light emitting chip or multiple such chips forming an array are disposed directly on a heat dissipating base, and the light emitting surfaces of the chips are bare. A collimating device (also called a collimator) or multiple collimating devices forming an array are aligned with the solid-state light emitting chips, to collimate the light emitted by the chips into near-parallel light for output. The divergence half-angle of the near-parallel light is limited to ±15° or less, depending on the application of the light source.

The solid-state light emitting chips may be, but are not limited to, semiconductor light emitting chips, such as light emitting diode chips. LED chips are used as an example in the description below.

FIG. 3 illustrates an encapsulation structure for a single LED chip according to an embodiment of the present invention. The structure includes a heat dissipating base 2 and an LED chip 1 disposed or encapsulated on the heat dissipating base. The light emitting surface of the LED chip is exposed to air. The structure further includes a collimating device 5, which is mounted over the LED chip 1 and is aligned with the chip. The collimating device 5 can simply be a focusing lens to focus the large angle light from the light emitting chip into near-parallel light for output. The collimating device 5 may also employ a lens array, although such a structure will be more complex and costly. The focusing lens may be an aspherical plastic or glass lens, or high refractive glass spherical lens. The lower surface of the lens 5 facing the chip 1 may be concave, planar (as shown), or even convex. A support frame 6 placed on the heat dissipating base 2 may be used to support the focusing lens 5. Alternatively, an encapsulating shell structure may be used to join the heat dissipating base 2 and the collimating device 5. A space is formed between the heat dissipating base 2 and the collimating device 5 to accommodate and encapsulate the LED chip 1, so that the lower surface of the focusing lens is kept at a distance from the top surface of the LED chip, separated by air which has a refractive index of 1. This protects the LED chip 1 from mechanical damage and reduces the etendue of the light source. Although the light flux of the light source may be lower than that of the conventional technologies, from the standpoint of the overall optical system, the light efficiency of the system is higher.

To effectively collect the light emitted by the LED chip 1, the distance between the focusing lens 5 and the top surface of the chip 1 is preferably no larger than 50% of the diameter of a bounding circle of the chip.

FIG. 4 illustrates an encapsulation structure for multiple LED chips forming an array according to another embodiment of the present invention. A difference between this embodiment and that of FIG. 3 is that multiple collimating devices are provided, forming an array, each collimating device being aligned with one LED chip. Preferably, the multiple collimating devices are joined to each other and formed integrally. Existing technologies provide suitable collimating device arrays; for example, Chinese Patent No. 200720196085 discloses a lens array that can be used for this purpose, and its structure is not described in detail here. Assuming that the light emitting area of each individual chip is 1 mm², the etendue E of the light source is proportional to the square of the refractive index and the number of LED chips in the array. In this embodiment, because the refractive index n of air is 1, the light source can maintain the etendue while increase the number of LED chips, resulting in both increased output brightness and increased flux.

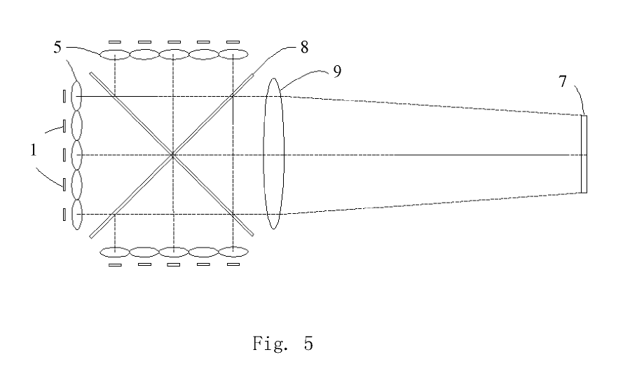

In a projection system employing a light source according to embodiments of the present invention, multiple LED chip arrays may be used to increase output brightness. Using an example of a stage lighting device (but the invention is not limited thereto), as shown in FIG. 5, the lighting device may include three monochromatic light sources, each including multiple LED chips emitting at the same wavelengths, such as red, green and blue lights. A light combining device 8, such as (but not limited to) an X shaped wavelength-based filter device, may be used with each of its three light input ports aligned with one light source. This configuration combines the light from the multiple solid state light emitting chip arrays into one high power light beam, while maintaining the etendue of the combined light beam. The combined light beam is directed to a focusing lens 9, which focuses the light onto a pattern plate 7 or a pattern carried on the pattern plate. Due to limitations on the size of the projection lens and the high image quality requirement, the projection system imposes certain requirements on the angle of the light impinging on the pattern 7. Because the light source according to embodiments of the present invention has low etendue, the light utilization efficiency and light flux of the projection system is increased, as can be illustrated by the comparison below.

Using an example of a stage lighting device which has a pattern plate with an effective diameter of 24 mm, and a projection lens with an FNO (i.e. focal distance/input aperture or effective aperture) of 1.8, the etendue of the lens is E(p)=π.(24/2)². (sin(π. 16/180))²=34. Assuming that the light collection angle of each individual LED chip is ±60°, under a requirement that the etendue of the projection lens E(p) is greater or equal to the etendue of the light source E(s), and using a refractive index of n=1.5 for the encapsulating lens in the example of FIG. 1, it can be calculated that a light source of the current technology (FIG. 1) would allow for a maximum number of 20 LEDs in the LED array, while the present embodiments allow a maximum number of 45 LEDs in the LED array. Assuming that the light flux of each LED chip provided by the current encapsulation technology (FIG. 1) is 20% greater than that of the present embodiments, it can be calculated that the light flux of the light source according to the present embodiments is higher than that of the current technology by a factor of 45/(20.(1+20%))=1.88.

1. A method for encapsulating solid-stage light emitting chips, comprising:
providing a solid-state light emitting chip, or multiple solid-state light emitting chips, directly on a heat dissipating base, a light emitting surface of each solid-state light emitting chip being bare; and
providing a collimating device, or multiple collimating devices, each collimating device being aligned with a solid-state light emitting chip, to collimate lights emitted by the solid-state light emitting chips into near-parallel lights for output.

2. The method of claim 1, wherein the collimating devices are focusing lens.

3. The method of claim 1, further comprising:
supporting the collimating devices on a support frame placed on the heat dissipating base, wherein each collimating device is located directly above a solid-state light emitting chip.

4. The method of claim 1, wherein the solid-state light emitting chips are semiconductor light emitting chips.

5. The method of claim 1, wherein the solid-state light emitting chips are light emitting diode chips.

6. The method of claim 1, wherein a divergence half-angle of the near-parallel light is ±15°.

7. An encapsulation structure for solid-stage light emitting chips, comprising:
a heat dissipating base;
a solid-state light emitting chip, or multiple solid-state light emitting chips, disposed on the heat dissipating base, a light emitting surface of each solid-state light emitting chip being bare and exposed to air; and
a collimating device, or multiple collimating devices, each collimating device being disposed above and aligned with a solid-state light emitting chip, to collimate lights emitted by the solid-state light emitting chips into near-parallel lights for output.

8. The encapsulation structure of claim 7, wherein the collimating devices are focusing lens.

9. The encapsulation structure of claim 7, further comprising:
a support frame placed on the heat dissipating base for supporting the collimating devices.

10. The encapsulation structure of claim 7, further comprising:
an encapsulating shell structure joining the heat dissipating base and the collimating devices, forming a space between the heat dissipating base and the collimating devices to accommodate the solid-state light emitting chips.

11. The encapsulation structure of claim 7, wherein a distance between each collimating device and the light emitting surface of the corresponding solid-state light emitting chip is no larger than 50% of a diameter of a bounding circle of the solid-state light emitting chip.

12. A light source comprising the solid-state light emitting chips and the encapsulation structure of claim 7.

13. A lighting device, comprising:
a heat dissipating base;
three solid-state light emitting chip arrays disposed on the heat dissipating base, each being formed by multiple solid-state light emitting chips emitting at common wavelengths, a light emitting surface of each solid-state light emitting chip being bare and exposed to air;
a plurality of collimating device arrays, each being formed by multiple collimating devices, each collimating device being disposed above and aligned with a solid-state light emitting chip, to collimate lights emitted by the solid-state light emitting chips into near-parallel lights for output;
a light combining device for combining light from the three solid state light emitting chip arrays via the collimating device arrays into one light beam;
a pattern plate or a pattern carried on the pattern plate; and
a focusing lens receiving the combined light beam and focusing it onto the pattern plate or the pattern.

14. The method of claim 1, wherein the multiple solid-state light emitting chips form an array and the multiple collimating devices form an array.

15. The method of claim 1, wherein the multiple focusing lenses are joined to each other and formed integrally.

16. The method of claim 2, further comprising:
supporting the collimating devices on a support frame placed on the heat dissipating base, wherein each collimating device is located directly above a solid-state light emitting chip.

17. The method of claim 4, wherein the solid-state light emitting chips are light emitting diode chips.

18. The encapsulation structure of claim 7, wherein the multiple solid-state light emitting chips form an array and the multiple collimating devices form an array.

19. The encapsulation structure of claim 7, wherein the multiple focusing lenses are joined to each other and formed integrally.

20. The encapsulation structure of claim 9, further comprising:
an encapsulating shell structure joining the heat dissipating base and the collimating devices, forming a space between the heat dissipating base and the collimating devices to accommodate the solid-state light emitting chips.
